(19) United States
(12) Patent Application Publication
(10) Pub. No.: US 2026/0344049 A1
(43) Pub. Date: Oct. 29, 2026

(54) CIRCUIT ARRAY SUBSTRATE

(71) Applicant: AUO Corporation, Hsinchu City (TW)

(72) Inventors: FangMing Tsao, Hsinchu City (TW); Kai-Teng Chiang, Hsinchu City (TW); Chun-Ru Huang, Hsinchu City (TW); Che-Min Lin, Hsinchu City (TW); Chu-Kuan Yu, Hsinchu City (TW); Meng-Chiou Huang, Hsinchu City (TW); Yi-Hsin Chou, Hsinchu City (TW); Chun-Hsin Tai, Hsinchu City (TW)

(73) Assignee: AUO Corporation, Hsinchu City (TW)

(21) Appl. No.: 19/641,569

(22) Filed: Apr. 8, 2026

Related U.S. Application Data
(60) Provisional application No. 63/796,419, filed on Apr. 29, 2025.

(30) Foreign Application Priority Data
Oct. 29, 2025 (TW) 114141881

(51) Int. Cl. H10D 86/40

(52) U.S. Cl. CPC H10D 86/481

(57) ABSTRACT

A circuit array substrate includes a plurality of pixel units, wherein each of the pixel units includes a gate electrode layer, a semiconductor layer, a storage capacitor, and a control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to a first source/drain electrode of the first transistor. A conductive plate of the control capacitor is electrically connected to a second source/drain electrode of the first transistor.

### CROSS-REFERENCE TO RELATED APPLICATION

This application claims the priority benefit of US provisional application serial no. 63/796,419 filed on Apr. 29, 2025 and Taiwan application serial no. 114141881, filed on Oct. 29, 2025. The entirety of each of the above-mentioned patent applications is hereby incorporated by reference herein and made a part of this specification.

### BACKGROUND OF THE INVENTION

### Field of the Invention

The invention relates to a circuit array substrate.

### Description of Related Art

After the scan signal is gated off, the storage capacitor (Cₛₜ) on the circuit array substrate may experience a voltage drop, reducing the yield of the electronic equipment.

### SUMMARY OF THE INVENTION

The invention provides a circuit array substrate that may prevent voltage drop in a storage capacitor therein.

According to an embodiment of the invention, a circuit array substrate is provided, including a plurality of pixel units, wherein each of the pixel units includes a gate electrode layer, a semiconductor layer, a storage capacitor, and a control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to a first source/drain electrode of the first transistor. A conductive plate of the control capacitor is electrically connected to a second source/drain electrode of the first transistor.

According to an embodiment of the invention, a circuit array substrate is provided, including a plurality of pixel units, wherein each of the pixel units includes a gate electrode layer, a semiconductor layer, a storage capacitor, and a control capacitor. The gate electrode layer includes a first portion extending in a first direction and a second portion extending in a second direction, wherein the first direction is not parallel to the second direction. The semiconductor layer and the first portion of the gate electrode layer form a first transistor, and the semiconductor layer and the second portion of the gate electrode layer form a second transistor. A conductive plate of the storage capacitor is electrically connected to a first source/drain electrode of the first transistor. A conductive plate of the control capacitor is electrically connected to a second source/drain electrode of the first transistor. A ratio of a capacitance of the control capacitor to a capacitance of the storage capacitor falls within a range of 1/65 to 1/55.

Based on the above, the circuit array substrate provided in an embodiment of the invention uses a control capacitor to avoid voltage drop in the storage capacitor, and the control capacitor does not affect the charging rate of the pixel unit to which it belongs.

To make the above features and advantages of the invention more apparent and understandable, specific embodiments are described below in conjunction with the accompanying drawings.

### BRIEF DESCRIPTION OF THE DRAWINGS

FIG. 1A shows a planar schematic diagram of a circuit array substrate according to the first embodiment of the invention, FIG. 1B shows a cross-sectional schematic diagram of a portion of the structure in FIGS. 1A, and 1C shows a circuit diagram of a portion of the structure in FIG. 1A.

FIG. 2 shows a schematic cross-sectional view of a circuit array substrate according to the second embodiment of the invention.

FIG. 3 shows a schematic cross-sectional view of a circuit array substrate according to the third embodiment of the invention.

FIG. 4 shows a schematic cross-sectional view of a circuit array substrate according to the fourth embodiment of the invention.

### DESCRIPTION OF THE EMBODIMENTS

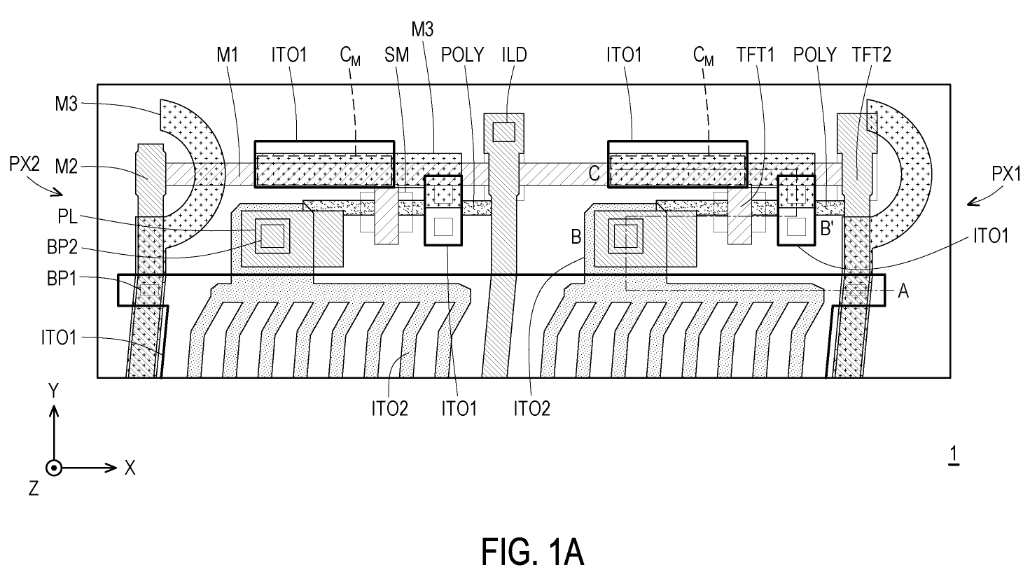

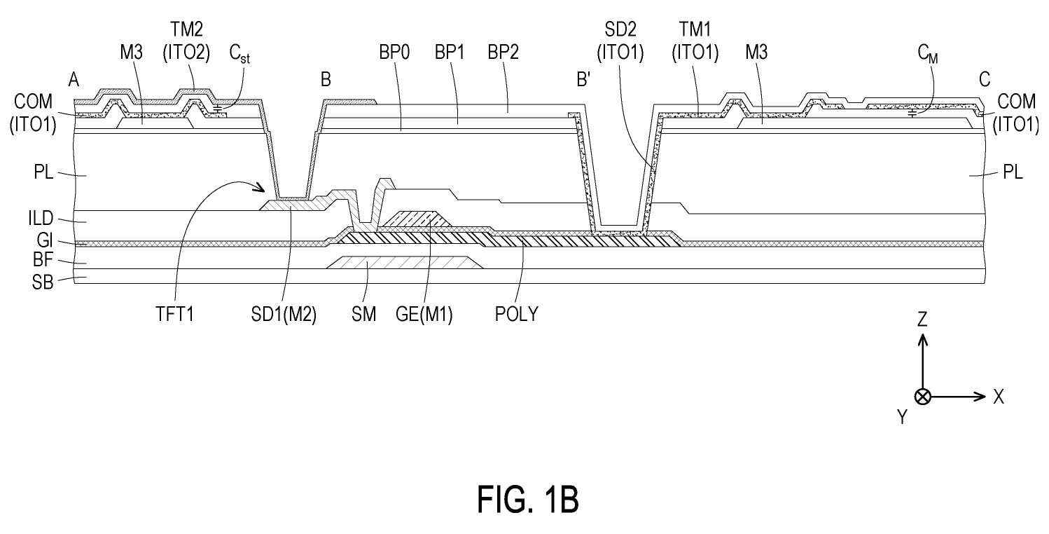

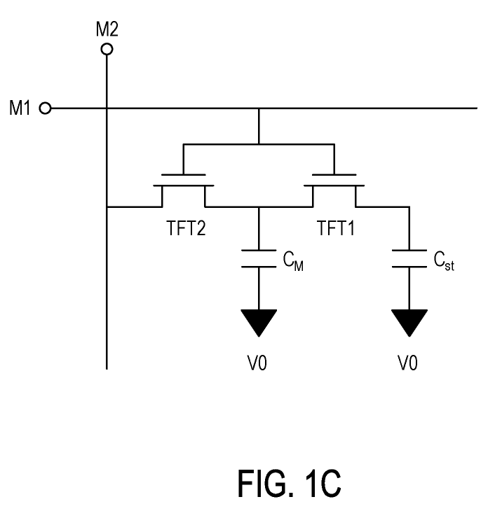

Referring to FIGS. 1A-1C, wherein FIG. 1A shows a planar schematic diagram of a circuit array substrate according to the first embodiment of the invention, FIG. 1B shows a cross-sectional schematic diagram of a portion of the structure in FIGS. 1A, and 1C, shows a circuit diagram of a portion of the structure in FIG. 1A.

A circuit array substrate 1 includes a plurality of pixel units PX1 and PX2, wherein each of the pixel units includes a gate electrode layer M1, a semiconductor layer POLY, a storage capacitor Cₛₜ, and a control capacitor C_{M}.

The gate electrode layer M1 includes a first portion extending in the Y direction and a second portion extending in the X direction, wherein the X direction is perpendicular to the Y direction. However, the invention is not limited to the above vertical relationship. The extension direction of the first portion of the gate electrode layer M1 may be neither parallel to nor perpendicular to the extension direction of the second portion of the gate electrode layer M1.

The semiconductor layer POLY and the first portion of the gate electrode layer M1 form a first transistor TFT1, and the semiconductor layer POLY and the second portion of the gate electrode layer M1 form a second transistor TFT2, as shown in FIG. 1A. Specifically, as shown in FIG. 1B, the first transistor TFT1 is disposed on a substrate SB and includes the semiconductor layer POLY, a gate electrode GE, a first source/drain electrode SD1, a second source/drain electrode SD2, and a gate insulating layer GI located between the gate electrode GE and the semiconductor layer POLY, wherein the first source/drain electrode SD1 is portion of a data line layer M2.

The circuit array substrate 1 also has a shielding metal SM, a buffer layer BF located between the semiconductor layer POLY and the shielding metal SM, and an interlayer insulating layer ILD on the gate insulating layer GI disposed on the substrate SB, wherein the shielding metal SM may be formed from a single layer or multiple layers of any of molybdenum (Mo), copper (Cu), titanium (Ti), aluminum (Al), chromium (Cr), gold (Au), nickel (Ni), neodymium (Nd), or alloys thereof. The buffer layer BF may include, for example, at least one of silicon oxide (SiOx) or silicon nitride (SiNx). The interlayer insulating layer (ILD) may include, for example, at least one of silicon oxide (SiOx) or silicon nitride (SiNx).

Furthermore, the circuit array substrate 1 also has a planarization layer PL, a dielectric layer BP0, a metal layer M3, a dielectric layer BP1, a transparent conductive layer ITO1, a dielectric layer BP2, and a transparent conductive layer ITO2 sequentially disposed on the interlayer insulating layer ILD. The transparent conductive layer ITO1 includes a transparent electrode layer TM1 and a common electrode layer COM, wherein the transparent electrode layer TM1 and the common electrode layer COM are disposed in the same layer and the materials thereof are the same. The transparent conductive layer ITO2 includes a transparent electrode layer TM2.

In the first embodiment, a conductive plate of the storage capacitor Cₛₜ is the transparent electrode layer TM2, and the transparent electrode layer TM2 is electrically connected to the first source/drain electrode SD1 of the first transistor TFT1 and serves as the pixel electrode of the pixel unit (PX1). Another conductive plate of the storage capacitor Cₛₜ is the common electrode layer COM, and the common electrode layer COM is subjected to a common voltage V0.

Moreover, a conductive plate of the control capacitor C_{M} is the metal layer M3, the metal layer M3 is electrically connected to the transparent electrode layer TM1, and the transparent electrode layer TM1 is electrically connected to the second source/drain electrode SD2 of the first transistor TFT1. Another conductive plate of the control capacitor C_{M} is the common electrode layer COM.

It should be noted that, referring to FIGS. 1B and 1C at the same time, the metal layer M3 of the control capacitor C_{M} is also electrically connected to one source/drain electrode of the second transistor TFT2. According to the scan signal provided to the gate electrode layer M1, the storage capacitor Cₛₜ and the control capacitor C_{M} may be charged simultaneously by the data voltage provided by the data line layer M2. When the scan signal is gated off, the voltage drop at the transparent electrode layer TM2 of the storage capacitor Cₛₜ may be avoided based on the voltage at the metal layer M3 of the control capacitor C_{M}. Furthermore, the capacitance of the control capacitor C_{M} is configured to be 1/65 to 1/55 of the capacitance of the storage capacitor Cₛₜ, thereby ensuring that the increased control capacitor C_{M} does not affect the charging rate of the corresponding pixel unit. However, the invention is not limited thereto. In some embodiments, the ratio of the capacitance of the control capacitor C_{M} to the capacitance of the storage capacitor Cₛₜ may fall within the range of 1/65 to 1/40, or be greater than 1/40. It should also be noted that the thickness of the dielectric layer BP1 of the control capacitor C_{M} may be, for example, between 200 Å and 8000 Å, between 200 Å and 7000 Å, between 200 Å and 6000 Å, between 200 Å and 5000 Å, between 200 Å and 4000 Å, between 200 Å and 2000 Å, between 200 Å and 1000 Å, between 200 Å and 7000 Å, and between 200 Å and 500 Å. Reducing the thickness of the dielectric layer BP1 of the control capacitor C_{M} may decrease the area of the metal layer M3 of the control capacitor C_{M}.

To fully illustrate the various embodiments of the invention, other embodiments of the invention will be described below. It should be noted that the following embodiments adopt the reference numerals and some content of the above embodiments, wherein the same reference numerals are used to represent the same or similar elements, and the description of the same technical content is omitted. For explanations regarding the omitted parts, please refer to the above embodiments, which are not repeated in the following embodiments.

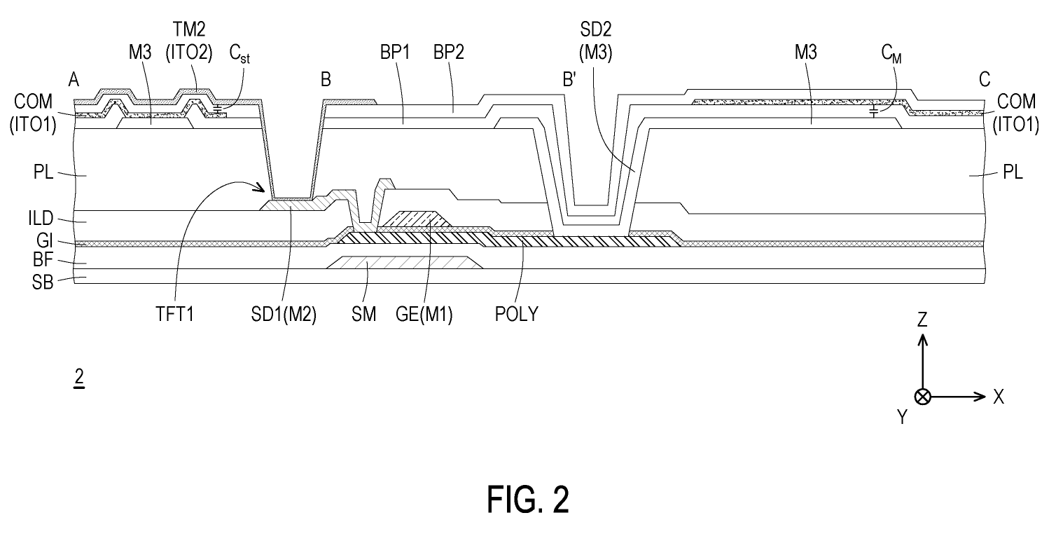

Referring to FIG. 2, a schematic cross-sectional view of a circuit array substrate 2 according to the second embodiment of the invention is shown.

In the circuit array substrate 2 of the second embodiment, a conductive plate of the control capacitor C_{M} is the metal layer M3, and another conductive plate thereof is the common electrode layer COM. The thickness of the dielectric layer BP1 of the control capacitor C_{M} may be, for example, between 200 Å and 8000 Å, between 200 Å and 7000 Å, between 200 Å and 6000 Å, between 200 Å and 5000 Å, between 200 Å and 4000 Å, between 200 Å and 2000 Å, between 200 Å and 1000 Å, between 200 Å and 7000 Å, and between 200 Å and 500 Å.

The circuit array substrate 2 differs from the circuit array substrate 1 at least in that the metal layer M3 includes the second source/drain electrode SD2 of the first transistor TFT1. That is, the materials of the conductive plate (M3) of the control capacitor C_{M} and the second source/drain electrode SD2 of the first transistor TFT1 are the same.

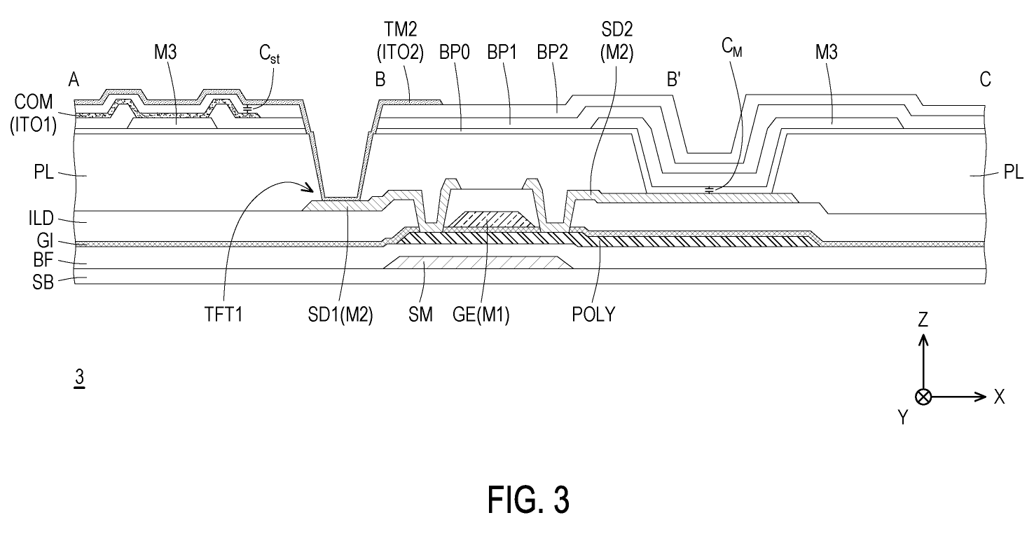

Referring to FIG. 3, a schematic cross-sectional view of a circuit array substrate 3 according to the third embodiment of the invention is shown.

In the circuit array substrate 3 of the third embodiment, a conductive plate of the control capacitor C_{M} is the metal layer M2, and the metal layer M2 is electrically connected to the second source/drain electrode SD2 of the first transistor TFT1. Another conductive plate of the control capacitor C_{M} is the metal layer M3, and the metal layer M3 may be used to transmit a touch signal. The thickness of the dielectric layer BP0 of the control capacitor C_{M} may be, for example, between 200 Å and 8000 Å, between 200 Å and 7000 Å, between 200 Å and 6000 Å, between 200 Å and 5000 Å, between 200 Å and 4000 Å, between 200 Å and 2000 Å, between 200 Å and 1000 Å, between 200 Å and 7000 Å, and between 200 Å and 500 Å. However, the invention is not limited thereto. In some embodiments, the common voltage V0 may be applied to the metal layer M3 of the control capacitor C_{M} and the common electrode layer COM of the storage capacitor Cₛₜ, thereby avoiding voltage drop at the transparent electrode layer TM2 of the storage capacitor Cₛₜ. In some embodiments, the metal layer M3 of the control capacitor C_{M} may be used to transmit DC signals.

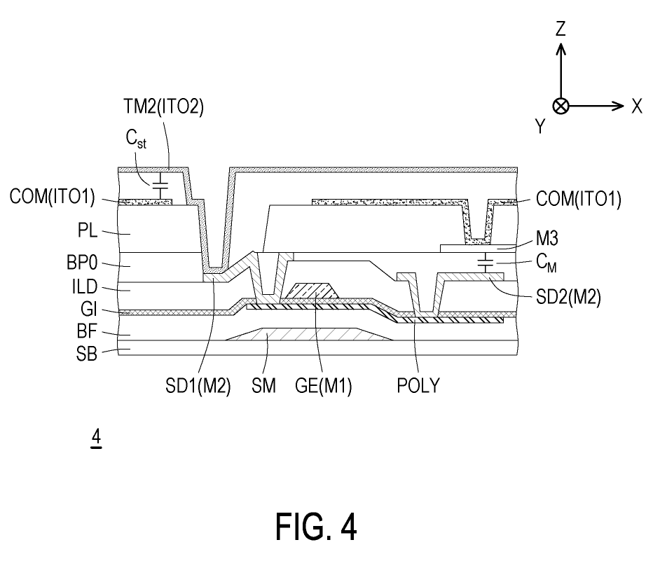

Referring to FIG. 4, a schematic cross-sectional view of a circuit array substrate 4 according to the fourth embodiment of the invention is shown.

In the circuit array substrate 4 of the fourth embodiment, a conductive plate of the control capacitor C_{M} is the metal layer M2, and the metal layer M2 is electrically connected to the second source/drain electrode SD2 of the first transistor TFT1. Another conductive plate of the control capacitor C_{M} is the metal layer M3, and the metal layer M3 is electrically connected to the common electrode layer COM. The thickness of the dielectric layer BP0 of the control capacitor C_{M} may be, for example, between 200 Å and 8000 Å, between 200 Å and 7000 Å, between 200 Å and 6000 Å, between 200 Å and 5000 Å, between 200 Å and 4000 Å, between 200 Å and 2000 Å, between 200 Å and 1000 Å, between 200 Å and 7000 Å, and between 200 Å and 500 Å.

Based on the above, the circuit array substrate provided in an embodiment of the invention utilizes a control capacitor to prevent voltage drop in the storage capacitor, and the control capacitor does not affect the charging rate of the pixel unit to which it belongs.

What is claimed is:

1. A circuit array substrate, comprising a plurality of pixel units, wherein each of the pixel units comprises:
a gate electrode layer comprising a first portion extending in a first direction and a second portion extending in a second direction, wherein the first direction is not parallel to the second direction;
a semiconductor layer, wherein the semiconductor layer and the first portion of the gate electrode layer form a first transistor, and the semiconductor layer and the second portion of the gate electrode layer form a second transistor;
a storage capacitor, wherein a conductive plate of the storage capacitor is electrically connected to a first source/drain electrode of the first transistor; and
a control capacitor, wherein a conductive plate of the control capacitor is electrically connected to a second source/drain electrode of the first transistor.

2. The circuit array substrate of claim 1, further comprising a common electrode layer, and another conductive plate of the control capacitor is the common electrode layer.

3. The circuit array substrate of claim 2, wherein another conductive plate of the storage capacitor is the common electrode layer.

4. The circuit array substrate of claim 2, wherein the second source/drain electrode is electrically connected to a transparent conductive layer, and materials of the transparent conductive layer and the common electrode layer are same.

5. The circuit array substrate of claim 4, wherein the conductive plate of the control capacitor is a metal layer.

6. The circuit array substrate of claim 1, further comprising a metal layer, wherein the metal layer forms another conductive plate of the control capacitor and the metal layer is used to transmit a touch signal.

7. The circuit array substrate of claim 1, wherein the control capacitor comprises a dielectric layer, and a thickness of the dielectric layer is between 200 Å and 8000 Å.

8. The circuit array substrate of claim 7, wherein the thickness of the dielectric layer is between 200 Å and 4000 Å.

9. The circuit array substrate of claim 1, wherein the conductive plate of the control capacitor is electrically connected to a source/drain electrode of the second transistor.

10. The circuit array substrate of claim 1, wherein the conductive plate of the storage capacitor is a pixel electrode of the pixel unit.

11. The circuit array substrate of claim 1, wherein a ratio of a capacitance of the control capacitor to a capacitance of the storage capacitor falls within a range of 1/65 to 1/40.

12. A circuit array substrate, comprising a plurality of pixel units, wherein each of the pixel units comprises:
a gate electrode layer comprising a first portion extending in a first direction and a second portion extending in a second direction, wherein the first direction is not parallel to the second direction;
a semiconductor layer, wherein the semiconductor layer and the first portion of the gate electrode layer form a first transistor, and the semiconductor layer and the second portion of the gate electrode layer form a second transistor;
a storage capacitor, wherein a conductive plate of the storage capacitor is electrically connected to a first source/drain electrode of the first transistor; and
a control capacitor, wherein a conductive plate of the control capacitor is electrically connected to a second source/drain electrode of the first transistor,
wherein a ratio of a capacitance of the control capacitor to a capacitance of the storage capacitor falls within a range of 1/65 to 1/55.

13. The circuit array substrate of claim 12, further comprising a common electrode layer, and another conductive plate of the control capacitor is the common electrode layer.

14. The circuit array substrate of claim 13, wherein another conductive plate of the storage capacitor is the common electrode layer.

15. The circuit array substrate of claim 13, wherein the second source/drain electrode is electrically connected to a transparent conductive layer, and materials of the transparent conductive layer and the common electrode layer are same.
